(19) United States
(12) Patent Application Publication
(10) Pub. No.: US 2011/0050365 A1
(43) Pub. Date: Mar. 3, 2011

(54) SIGNAL TRANSMISSION APPARATUS

(75) Inventors: YU-CHANG PAI, Tu-Cheng (TW); PO-CHUAN HSIEH, Tu-Cheng (TW); CHIEN-HUNG LIU, Tu-Cheng (TW)

(73) Assignee: HON HAI PRECISION INDUSTRY CO., LTD., Tu-Cheng (TW)

(21) Appl. No.: 12/647,527

(22) Filed: Dec. 27, 2009

(30) Foreign Application Priority Data
Aug. 26, 2009 (CN) 200910306135.X

(51) Int. Cl. H03H 7/01

(52) U.S. Cl. 333/185; 333/175

(57) ABSTRACT

A signal transmission apparatus includes a first ground layer, a second ground layer and a band pass filter. The band pass filter includes a first transmission line positioned in a void defined in the first ground layer and a second transmission line positioned in a void defined in the second ground layer. Each of the first transmission line and the second transmission line includes a coil with a plurality of turns spirally extending in the same plane, a gasket extending from the coil and located in the center of the coil, and a signal terminal extending from extremity of the coil. According to employing the band pass filter, the signal transmission apparatus has filtering function, therefore, quality of signals transmitted through the signal transmission apparatus is improved.

### BACKGROUND

1. Technical Field

The present disclosure relates to signal transmission apparatuses, and particularly to a signal transmission apparatus used in a signal receiver or a signal transceiver of a wireless transmission system.

2. Description of Related Art

Wireless transmissions are widely used in communications and networks. Consequently, electronic devices can be moved freely without limitations of wires when transmitting signals. In a wireless transmission system, a signal for transmission is modulated by a high frequency carrier in a signal transceiver to generate a radio frequency signal. The radio frequency signal is transmitted to a signal receiver via air, and is demodulated into the signal for transmission in the signal receiver. However, bad signal quality may be induced if the signal transceiver and the signal receiver of the wireless transmission system are improperly designed.

### BRIEF DESCRIPTION OF THE DRAWINGS

FIG. 1 is an exploded, isometric view of a signal transmission apparatus according to an embodiment of the present disclosure, wherein the signal transmission apparatus includes a band pass filter.

FIG. 2 is a simulation graph of insertion loss of the band pass filter of the signal transmission apparatus of FIG. 1.

FIG. 3 is a simulation graph of return loss of the band pass filter of the signal transmission apparatus of FIG. 1.

### DETAILED DESCRIPTION

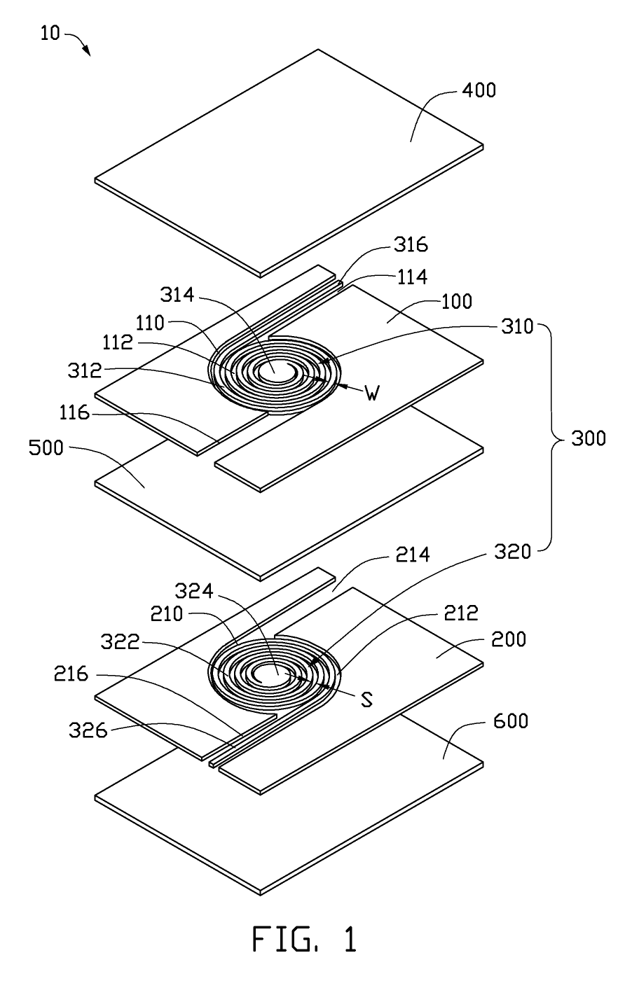

Referring to FIG. 1, an exemplary embodiment of a signal transmission apparatus 10 is positioned in a printed circuit board, and used in a signal receiver or a signal transceiver to transmit signals. The signal transmission apparatus 10 includes a first ground layer 100, a second ground layer 200, a band pass filter 300, a first insulation layer 400, a second insulation layer 500, and a third insulation layer 600. The first ground layer 100 is parallel to the second ground layer 200, and sandwiched between the first insulation layer 400 and the second insulation layer 500. The second ground layer 200 is sandwiched between the second insulation layer 500 and the third insulation layer 600. The first insulation layer 400 insulates the first ground layer 100 from external environment. The second insulation layer 500 insulates the first ground layer 100 from the second ground layer 200. The third insulation layer 600 insulates the second ground layer 200 from external environment. The band pass filter 300 includes a first transmission line 310 positioned in a void 110 defined in the first ground layer 100, and a second transmission line 320 positioned in a void 210 defined in the second ground layer 200. In one embodiment, each of the first ground layer 100 and the second ground layer 200 is made of conductive material, such as copper. The void 110 and the first transmission line 310 are formed by etching the conductive material of the first ground layer 100. The void 210 and the second transmission line 320 are formed by etching the conductive material of the second ground layer 200. Each of the first insulation layer 400, the second insulation layer 500, and the third insulation layer 600 may be made of glass fiber epoxy resin (FR-4) material.

The first transmission line 310 includes a first coil 312 with a plurality of turns spirally extending in the same plane to form a spiral path, a first gasket 314 located in the center of the first coil 312 and acting as the beginning of the first coil 312, and a first signal terminal 316 extending from extremity of the first coil 312 along a first direction. The second transmission line 320 includes a second coil 322 with a plurality of turns spirally extending in the same plane to form a spiral path, a second gasket 324 located in the center of the second coil 322 and acting as the beginning of the second coil 322, and a second signal terminal 326 extending from extremity of the second coil 322 along a second direction opposite to the first direction. The void 110 includes a central area 112, and two slots 114 and 116 respectively extending from two opposite edges of the first ground layer 100 to the central area 112. The void 210 includes a central area 212, and two slots 214 and 216 respectively extending from two opposite edges of the second ground layer 200 to the central area 212. The voids 110 and 210 have similar shapes, and a projection of the void 110 on the second ground layer 200 completely overlaps the void 210. The first transmission line 310 and the second transmission line 320 have similar shapes. A projection of a geometric center of the first gasket 314 on the second ground layer 200 completely overlaps a geometric center the second gasket 324. The first signal terminal 316 and the second signal terminal 326 extending along opposite directions, are used for transmitting and receiving signals. A projection of the first signal terminal 316 on the second ground layer 200 is within the slot 214 of the second ground layer 200, and a projection of the second signal terminal 326 on the first ground layer 100 is within the slot 116 of the first ground layer 100.

Filtering characteristics of the band pass filter 300 depend on the number of turns of the first and second coils 312 and 322, line width and line spacing of the spiral path of the first and second coils 312 and 322, areas of the first and second gaskets 314 and 324, and a distance between the first ground layer 100 and the second ground layer 200. Further details of factors that affect the filtering characteristics of the band pass filter 300 will be explained in further detail below. The number of turns of the first and second coils 312 and 322, and the line width and line spacing of spiral path of the first and second coils 312 and 322 mainly affect inductance effect of the band pass filter 300, thereby affect bandwidth responded by the band pass filter 300 and drifting of center frequency of the band pass filter 300. The more turns of the first and second coils 312 and 322, and the narrower line width and the shorter line spacing of spiral path of the first and second coils 312 and 322, the stronger inductance effect of the band pass filter 300, the wider bandwidth responded by the band pass filter 300, and the center frequency of the band pass filter 300 drifting to lower frequency. The areas of the first and second gaskets 314 and 324 mainly affect bandwidth responded by the band pass filter 300 and insertion loss of the band pass filter 300. The larger areas of the first and second gaskets 314 and 324, the wider bandwidth responded by the band pass filter 300, and the less insertion loss of the band pass filter 300. The distance between the first ground layer 100 and the second ground layer 200 mainly affects capacitance effect of the band pass filter 300. The shorter distance between the first ground layer 100 and the second ground layer 200, the stronger capacitance effect of the band pass filter 300.

In one embodiment, the first coil 312 and the second coil 322 have the same number of turns, the same line width and the same line spacing, the turns of the first coil 312 circularly spiral in the first ground layer 100, and the turns of the second coil 322 circularly spiral in the second ground layer 200. Each of the first gasket 314 and the second gasket 324 is a circular gasket, and the geometric center of each of the first gasket 314 and the second gasket 324 is a center of the circular gasket. Each of the central areas 112 and 212 is a circular hollow area. The slots 114 and 116 are parallel to each other and tangent to the central area 112. The slots 214 and 216 are parallel to each other and tangent to the central area 212.

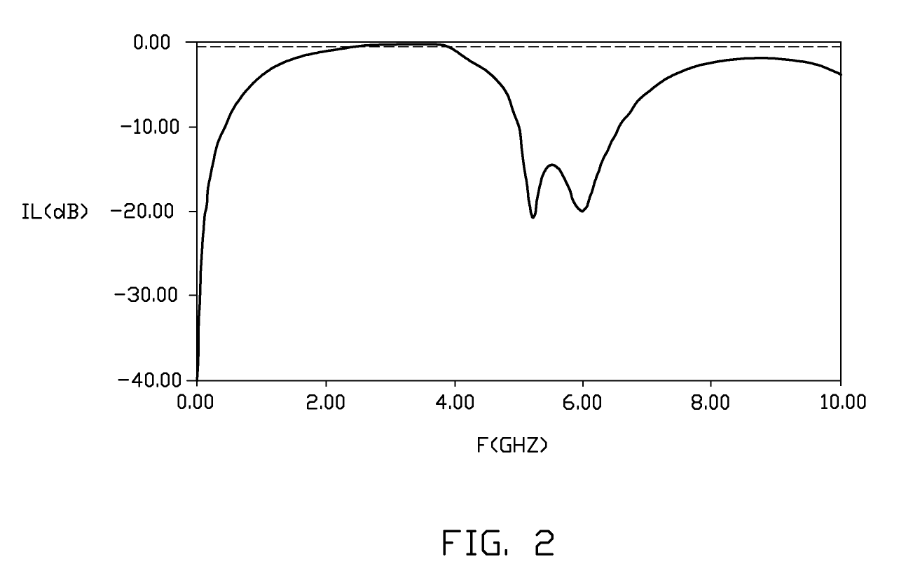

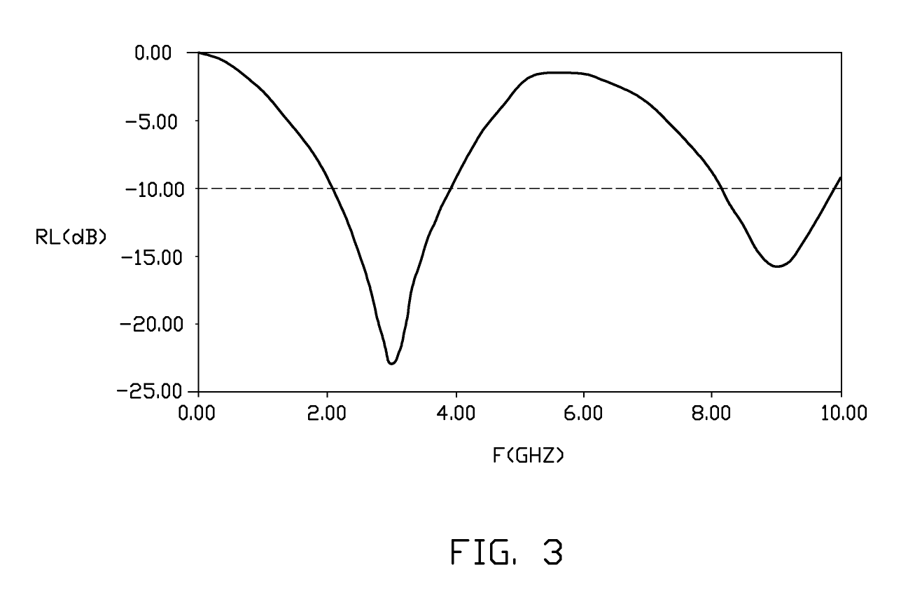

Referring to FIGS. 2 and 3, in one embodiment, parameters of the band pass filter 300 are as follows: the number of turns of each of the first coil 312 and the second coil 322 is about N=4; the line width of spiral path of each of the first coil 312 and the second coil 322 is about W=4 mils; the line spacing of spiral path of each of the first coil 312 and the second coil 322 is about S=4 mils; radius of each of the first gasket 314 and the second gasket 324 is about R=8 mils; the distance between the first ground layer 100 and the second ground layer 200 is about D=2 mils. The band pass filter 300 can be simulated using a simulation software according to the above-mentioned parameters, in order to obtain a graph of an insertion loss of the band pass filter 300 (shown in FIG. 2) and a graph of return loss of the band pass filter 300 (shown in FIG. 3).

In FIG. 2, the abscissa is a frequency F of a signal transmitted through the band pass filter 300, the ordinate is an insertion loss IL of the signal, and the more the ordinate of the graph closing to zero, the better performance of the band pass filter 300. In FIG. 3, the abscissa is a frequency F of a signal transmitted through the band pass filter 300, the ordinate is a return loss RL of the signal, and the smaller the ordinate of the graph, the better performance of the band pass filter 300. It can be seen in FIGS. 2 and 3 that a desired performance of the band pass filter 300 is achieved in a frequency band from 2.25 gigahertz (GHZ) to 3.85 GHZ, since the corresponding insertion loss values are close to zero and the corresponding return loss values are less than −10 decibels (dB). In other embodiments, the number of turns, the line width and line spacing of the first and second coils 312 and 322, the shape of the first and second coils 312 and 322, the first and second gaskets 314 and 324 and the voids 110 and 210, and the distance between the first ground layer 100 and the second ground layer 200, can be adjusted according to actual needs. Additionally, the signal transmission apparatus 10 not only can be used in wireless transmission devices, such as wireless network card and access point, but also can be used in wired transmission devices. Furthermore, according to employing the band pass filter 300, the signal transmission apparatus 10 has filtering function, therefore, quality of signals transmitted through the signal transmission apparatus 10 is improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A signal transmission apparatus comprising:
a first ground layer defining a first void;
a second ground layer parallel to the first ground layer, defining a second void having a similar structure to that of the first void, wherein a projection of the second void on the first ground layer overlaps the first void; and
a band pass filter comprising:
a first transmission line positioned in the first void, comprising:
a first coil with a plurality of turns spirally extending in the same plane to form a first spiral path;
a first gasket extending from the first coil and located in the center of the first coil; and
a first signal terminal extending from extremity of the first coil along a first direction; and
a second transmission line positioned in the second void, comprising:
a second coil with a plurality of turns spirally extending in the same plane to form a second spiral path;
a second gasket extending from the second coil and located in the center of the second coil; and
a second signal terminal extending from extremity of the second coil along a second direction opposite to the first direction;
wherein a projection of a geometric center of the first gasket on the second ground layer overlaps a geometric center of the second gasket, a projection of the first coil on the second ground layer is within the second void, and a projection of the second coil on the first ground layer is within the first void.

2. The signal transmission apparatus of claim 1, wherein the first coil and the second coil have the same number of turns, the first spiral path and the second spiral path have the same line width and the same line spacing.

3. The signal transmission apparatus of claim 1, wherein the turns of the first coil circularly spiral in the first ground layer, and the turns of the second coil circularly spiral in the second ground layer.

4. The signal transmission apparatus of claim 1, wherein each of the first gasket and the second gasket is circular in shape.

5. The signal transmission apparatus of claim 1, wherein the first void includes a first central area, and two first slots respectively extending from two opposite edges of the first ground layer to the first central area; and the second void includes a second central area, and two second slots respectively extending from two opposite edges of the second ground layer to the second central area.

6. The signal transmission apparatus of claim 5, wherein the first central area is circular in shape, and the two first slots of the first void are parallel to each other and tangent to the first central area; the second central area is circular in shape, and the two second slots of the second void are parallel to each other and tangent to the second central area; a projection of the first signal terminal on the second ground layer is within one of the two first slots of the first void; a projection of the second signal terminal on the first ground layer is within one of the two second slots of the second void.

7. The signal transmission apparatus of claim 1, wherein the first ground layer and the second ground layer are insulated from each other and external environment by insulation layers.

8. The signal transmission apparatus of claim 1, wherein each of the first ground layer and the second ground layer is made of conductive material; the first void and the first transmission line are formed by etching the conductive material of the first ground layer; the second void and the second transmission line are formed by etching the conductive material of the second ground layer.

9. A band pass filter comprising:
a first transmission line positioned in a first void defined in a first ground layer, comprising:
a first coil with a plurality of turns spirally extending in the same plane to form a spiral path;
a first gasket extending from the first coil and located in the center of the first coil; and
a first signal terminal extending from extremity of the first coil along a first direction; and
a second transmission line positioned in a second void defined in a second ground layer, comprising:
a second coil with a plurality of turns spirally extending in the same plane to form a spiral path;
a second gasket extending from the second coil and located in the center of the second coil; and
a second signal terminal extending from extremity of the second coil along a second direction opposite to the first direction;
wherein a projection of a geometric center of the first gasket on the second ground layer overlaps a geometric center of the second gasket, a projection of the first coil on the second ground layer is within the second void, and a projection of the second coil on the first ground layer is within the first void.

10. The band pass filter of claim 9, wherein the first coil and the second coil have the same number of turns, the first spiral path and the second spiral path have the same line width and the same line spacing.

11. The band pass filter of claim 9, wherein the turns of the first coil circularly spiral in the first ground layer, and the turns of the second coil circularly spiral in the second ground layer.

12. The band pass filter of claim 9, wherein each of the first gasket and the second gasket is circular in shape.
